(19) United States
(12) Patent Application Publication
(10) Pub. No.: US 2021/0282269 A1
(43) Pub. Date: Sep. 9, 2021

(54) PRINTED CIRCUIT BOARDS IMPREGNATED WITH CARBON NANO TUBES

(71) Applicant: Honeycomb Secure Systems, Inc., Guntersville, AL (US)

(72) Inventor: Thomas R. Goldberg, Bethesda, MD (US)

(73) Assignee: Honeycomb Secure Systems, Inc.

(21) Appl. No.: 17/194,250

(22) Filed: Mar. 6, 2021

Related U.S. Application Data
(60) Provisional application No. 62/986,715, filed on Mar. 8, 2020.

(51) Int. Cl. H05K 3/10; H05K 3/28; H05K 1/02; C23C 14/28; C23C 14/06

(52) U.S. Cl. CPC H05K 3/105; H05K 3/28; H05K 1/0237; H05K 2203/107; C23C 14/0605; H05K 2203/1509; C23C 14/28

(57) ABSTRACT

Embodiments of the present technology are directed at systems and methods for impregnating PCBs with CNT traces to create functional CNT-based PCBs. The functional CNT-based PCBs exhibit high structural stability and improved electrical and thermal properties. Based on fixed impregnation and densification techniques, perfect or near-perfect alignment of CNT traces on the PCB substrates is achieved. For example, application of the disclosed technology results in traces of CNTs aligned on a PCB substrate in parallel to one another in a butt-jointed arrangement from end-to-end of the PCB substrate. Advantageously, the disclosed methods eliminate occurrence of misorientation or misalignment of the CNT traces. Sensors and electrical/electronic devices built with PCBs using CNT traces provide significant advances for SWaP (reduced Size, Weight, and Power consumption).

### CROSS-REFERENCE TO RELATED APPLICATIONS

This application claims priority to U.S. Provisional Application No. 62/986,715 filed Mar. 8, 2020, which is incorporated herein by reference in its entirety.

### TECHNICAL FIELD

The present disclosure relates to high-performance printed circuit boards (PCBs) used in electrical and electronic circuits. Specifically, disclosed embodiments are related to PCBs impregnated with traces of carbon nanotubes (CNTs).

### BACKGROUND

PCBs are the backbone of all computers and microelectronic devices today, and are the core technology enabling all computers, communications devices and sensors. PCBs facilitate connections between multiple components on an electronic device for the transport of electrons and computational processes. Thus, there is a need for the design of high-performance PCBs.

### BRIEF DESCRIPTION OF THE DRAWINGS

FIG. 1 is a representation of CNTs in a 2-dimensional (2D) perspective.

FIG. 2 is a representation of CNTs in a 3-dimensional (3D) perspective.

FIGS. 3A and 3B respectively illustrate the electron (current) flow in metal and CNT conductors.

FIG. 4 is a simplified, high-level diagram showing alignment of CNTs.

FIG. 5 shows an example of PCB layers and structure.

FIG. 6A illustrates a simplified diagram of a physical vapor deposition (PVD) technique to affix CNTs onto a target (PCB).

FIG. 6B illustrates a vacuum chamber as part of a system for impregnating PCBs with CNTs.

FIG. 7 illustrates a simplified diagram showing a system for generating PCBs impregnated with CNTs.

FIG. 8 illustrates a conceptual diagram showing CNT vapors generated by the system for impregnating PCBs with CNTs.

FIG. 9 illustrates an example of an impregnated PCB.

### DETAILED DESCRIPTION

Embodiments of the present technology are directed at systems and methods for impregnating PCBs with CNT traces to create functional CNT-based PCBs. The functional CNT-based PCBs exhibit high structural stability and improved electrical and thermal properties. Based on fixed impregnation and densification techniques, perfect or near-perfect alignment of CNT traces on the PCB substrates is achieved. For example, application of the disclosed technology results in traces of CNTs aligned on a PCB substrate in parallel to one another in a butt-jointed arrangement from end-to-end of the PCB substrate. Advantageously, the disclosed methods eliminate occurrence of misorientation or misalignment of the CNT traces. Sensors and electrical/electronic devices built with PCBs using CNT traces provide significant advances for SWaP (reduced Size, Weight, and Power consumption).

In some embodiments, the system for impregnating PCBs with CNTs includes physical vapor deposition (PVD) inside a chamber designed to handle vacuum conditions. For example, the conditions in the chamber correspond to pressure ranging between 1×10⁻¹² atmospheres to 1×10⁻¹⁴ atmospheres, versus vacuum conditions in space correspond to 1×10⁻⁶to <1×10⁻¹⁷Torr, or equivalently 1×10⁻⁴ to <3×10⁻¹⁵ Pa. It will be appreciated that the vacuum conditions maintained inside the chamber can be regarded as resembling vacuum in outer space. In some embodiments, the chamber is constructed of high strength stainless steel having a wall thickness of about nine (9) inches. The chamber is fitted with multiple ports connected to vacuum pumps for evacuating the chamber. Upon achieving the vacuum conditions inside the chamber, the vacuum conditions are maintained for a specified time duration. Maintaining the vacuum conditions inside the chamber for a specified time duration prevents distortion of the unimpregnated PCB blanks and prevents damage to the chamber, shuttle, systems, and sensitive electronic control equipment. The disclosed process of creating CNT traces on PCB substrates achieves the greatest adhesion (resilience) possible between the traces and the substrate material. Under vacuum conditions generated within the chamber, Van der Waal forces effectively allow alignment and densification of CNT traces on PCB Blanks at near perfection. CNT adhesion forces (e.g., CNTs are among the most tenacious materials exhibiting adhesion) ensure that once applied, extraordinary forces are required to come free. Because CNTs are thermally-, chemically-, and radiation-inert, the force necessary to bend/brake CNT traces are outside of the realm of possibilities of almost all use cases. Moreover, the disclosed process of creating CNT traces on PCB substrates results in very thin and flexible substrates, which facilitates extremely low weight micro-electronic devices with highly-flexible substrates.

It will be understood that the disclosed system for impregnating PCBs with CNT traces does not rely on a specific physical vapor deposition methodology. Rather, the disclosed technology has broader applicability in getting integrated with a suitable physical vapor deposition methodology. In contrast to conventional physical vapor deposition techniques that are merely limited to applying CNTs as coatings to a substrate, embodiments of the present technology are directed at creating CNT-based PCBs that have near perfect alignment, a trace densification leading to high reliability, and improved electrical and thermal properties. Furthermore, the disclosed method of creating CNT traces on PCB blanks is a single step application that eliminates layering and create the highest quality product as opposed to either lithographic or direct-write PCB manufacturing processes. Traditional printed circuit board (PCB) manufacturing comprises multiple processes or steps. Furthermore, each step requires close control to minimize tolerance errors on each layer and between layers (e.g. via-to-pad registration). For example, masks and resists used in the image transfer to PCB layers require extreme control. Coupled with heated pressure lamination processes and handling when aligning layers, traditional techniques lead to dimensional distortions and flaws. While maskless direct-write tracing offers significant improvements over conventional lithographic processes, layering remains a challenge. The disclosed technology is directed at solving at least the above-mentioned problems in conventional systems and processes.

As used herein, the terms “PCB,” “blank,” “PCB blank,” “PCB substrate” are generally synonymous.

### Use of CNTs

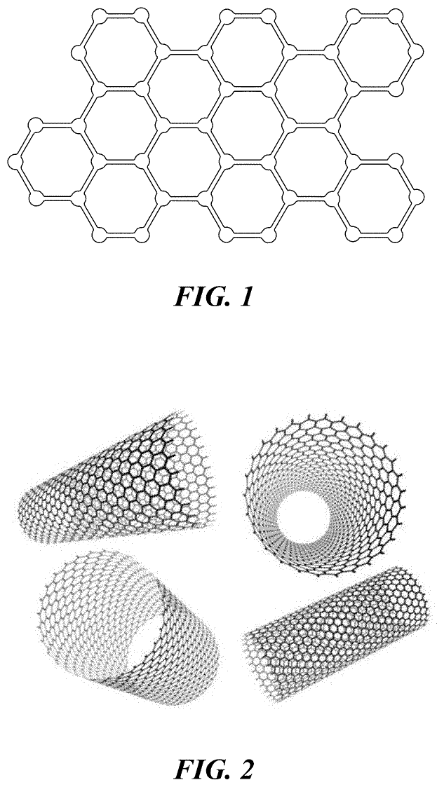

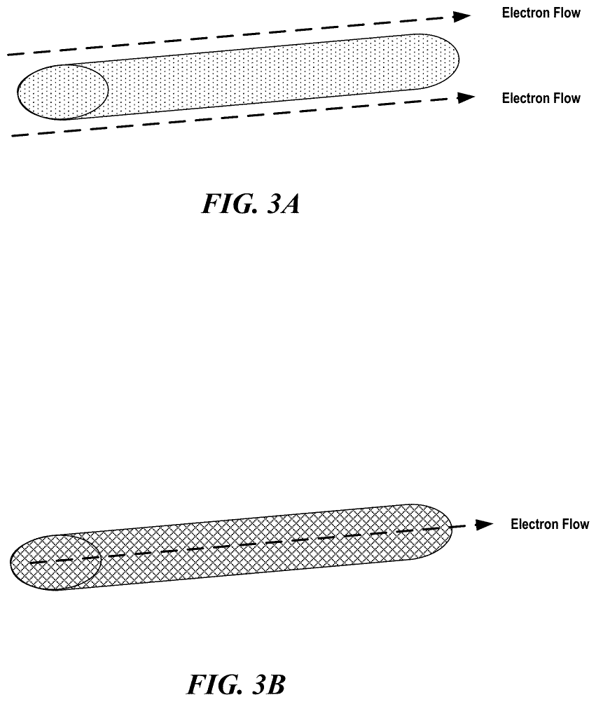

FIGS. 1 and 2 are representations of carbon nanotubes (CNTs) in 2D and 3D perspectives. CNTs are molecules composed of pure carbon in which atoms in a hexagonal lattice are positioned in a cylindrical form. CNTs exhibit certain properties making them well-suited in a wide variety of electronic and optical and physical applications. Semiconducting single-wall CNTs (sSWNTs) can be isolated and oriented in accordance with a pattern. For example, CNTs can be used to design non-volatile CNT-based memory. Non-volatile CNT-based memory provides a dramatic reduction in energy consumption, a thousand-fold increase in storage density, greater reliability, instant on/off capabilities, perpetual data storage, and no soft-errors in comparison to conventional Dynamic Random-Access Memory (DRAM).

CNTs can also be used as trace materials on PCBs (either as individual oriented sSWNTs or as oriented sSWNT-bundles) to create ultra-low impedance interconnects between components. The disclosed technology is directed at impregnating PCBs with CNTs such that the resultant PCB includes CNTs as the PCB trace material (in lieu of copper, silver, gold, or other metallic materials). Using semiconducting single-wall CNT traces in place of traditional conductors (e.g., metals such as copper, silver, and gold) prevents undesired electromagnetic emissions, requires almost no energy (e.g., in the range of milliamps), and facilitates the fastest (near-optical) electron flows between devices/components on a PCB. The near-optical electron flows facilitate buffer-less data flow rates to be enabled. Further, because CNTs offer no resistivity to electrons passing through them, they generate no heat and have reduced demand (e.g., by as much as 60%) for power consumption. Also, CNTs act as heat sinks, resulting in a PCB substrate that removes heat from electrical devices and components.

CNT impregnated PCBs are advantageous at least for the following reasons:

Enhanced Security—Elimination of ischemic (e.g., electromagnetic/RF) emissions prevents remote interrogation of devices and possible theft of data by microwave or laser excitation of wires, traces, microchips, capacitors, resists, etc. Because CNTs are impervious to ionizing radiation and are inert to such excitations, the transport of electrons across printed circuit boards are impervious to both natural and manmade attacks. As a result, the potential for interdiction, or interference of devices is eliminated. Thus, PCBs impregnated with CNTs are suitable for use in secure, autonomous devices and/or secure communications devices. Furthermore, in CNTs, electrons travel through the canal of CNTs rather on the surface. As a result, CNTs are protected from exposure. Additionally, the use of CNT traces on PCBs enables radical and advanced PCB device design modifications through the elimination of up to 60% of the threat surface on a PCB by allowing removal of interconnect and modifier devices/components placed between memory and logic of a computing device. As a result, the potential for interdiction, or interference of devices is eliminated.

Energy Reduction—CNT-based devices provide reduction of electric power demand by as much as 60%.

Improved Performance—CNTs provide improvements (in orders of magnitude) in performance at least across three areas. (i) CNTs offer no resistivity, resulting in “near-optical” transport between devices/components on a PCB. (ii) CNTs enable electron movements at very high speeds providing increased operational capabilities within memory and logic, in comparison to conventional materials (e.g. Au, Al, Si, etc.). The faster electron movements allow uninterrupted connections (e.g. elimination of controllers, resistors, etc.) between memory and logic components and allows computing devices to achieve their design potential. (iii) CNT traces deposited on a PCB substrate allow for a 60% reduction of devices/components on PCBs, further improving the performance of the PCB.

Greater Reliability—CNTs impart significant reliability enhancements to devices made using CNTs or devices/components that include CNTs. CNTs are the hardest materials next to diamond and exhibit significant performance characteristics. For example, CNTs exhibit thermal stability (i.e., CNTs have a negative coefficient of thermal expansion) because CNTs do not expand or contract when exposed to temperature. Also, CNTs are chemically inert, and resist acids and bases of any strength. Furthermore, CNTs are inert to ionizing radiation and can be deployed in space-related applications where devices/components are exposed to extreme solar weather conditions. CNT-based microelectronics have performed in High-Earth Orbit (HEO) for over fifteen years without failure and CNT-based Memory has had no “soft-errors” in over fifteen years. CNT-based circuits have a life expectancy of 1000 years at 80° C., and operational life of over 15 years at ±300° K.

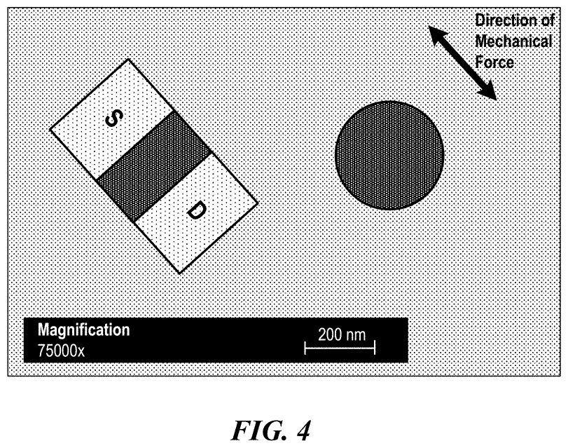

FIGS. 3A and 3B respectively illustrate the electron (current) flow in metal and CNT conductors. CNTs used in non-volatile memory and especially on PCBs provide low electrical impedance and generate almost no heat. Furthermore, CNTs provide high thermal conductivity and a negative coefficient of thermal expansion resulting in high structural stability. The thermal conductivity of CNTs makes them well-suited for thermal management (e.g., planar heat dissipation) in electronic devices and components, reducing the need for active cooling. FIG. 3A depicts electron flow in a conductor occurring at the surface of the conductor. On the other hand, FIG. 3B depicts electron flow in a CNT occurring within the PCB traces, as opposed to along the surface of conductors. As a result, CNTs are not susceptible to “weeping” effects (unlike ordinary metallic conductors like aluminum, copper gold, etc.), thereby providing electromagnetic shielding. The use of CNTs in non-volatile RAM or Nano-RAM results in higher density, capacity, and performance than existing DRAM. When combined with its data persistence, CNT-based RAM can replace existing hard and solid-state drives and the additional hardware and support controllers.

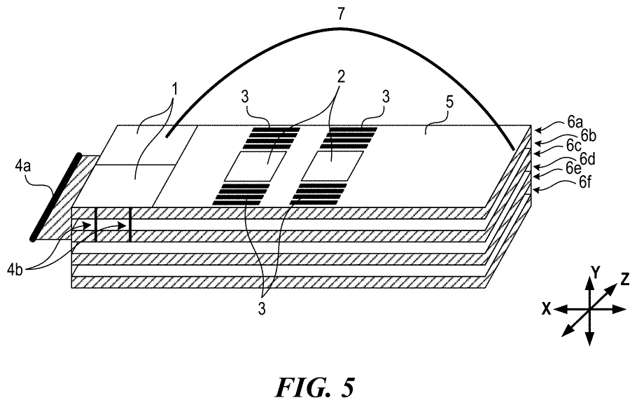

FIG. 4 is a simplified diagram showing alignment of CNT traces on PCB when observed under a scanning microscope. For example, FIG. 4 demonstrates perfect or near-perfect alignment of CNT traces as a result of impregnating semiconducting single-walled CNTs on a PCB substrate. FIG. 4 shows that the CNTs are aligned in parallel with one another, in a butt-jointed arrangement from end-to-end of the PCB substrate. For example, there is not misorientation or misalignment of the CNTs. The methods to achieve perfect or near-perfect alignment of CNTs on PCB substrates are disclosed in greater detail herein.

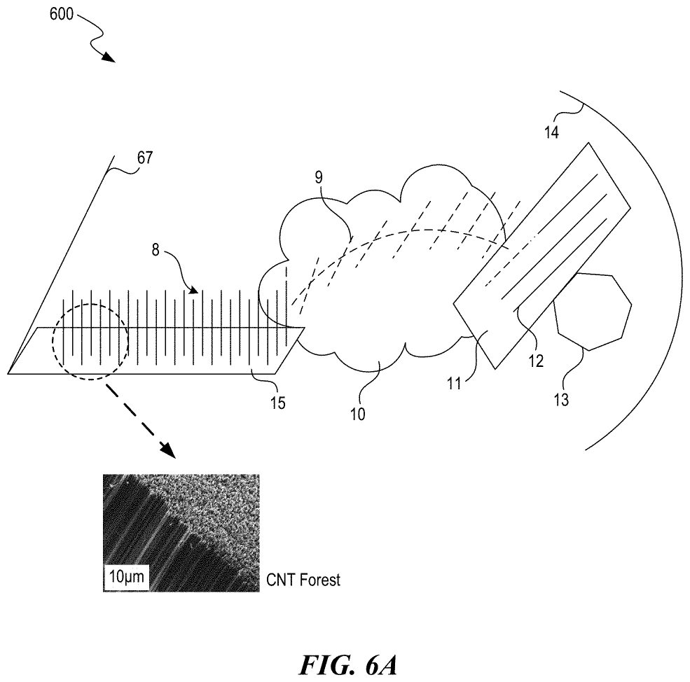

FIG. 5 shows an illustrative PCB impregnated with CNT traces. In the example shown in FIG. 5, the PCB impregnated with CNT traces is used in a blade server. Reference numeral 1 in FIG. 5 diagrammatically illustrates the PCB trace material based on CNTs. The blade server shown in FIG. 5 includes two central processing units (represented by reference numeral 2) and dual in-line CNT-based non-volatile random-access memory modules (represented by reference numeral 3). The CNT-based non-volatile random-access memory modules are a replacement of traditional file system storage based on hard disks and solid-state drives. The PCB shown in FIG. 5 utilizes electro-optical interfaces instead of metallic conductors. Reference numeral 4a shows an electro-optical interface for converting electrical signals to optical signals. The electrical signals may be routed using vias (represented by reference numeral 4b) to a control plane layer, or may simply travel across the board following proscribed traces (represented by reference numeral 7). Reference numeral 5 represents an unpopulated region on the PCB surface that allows increased airflow and thermal dissipation. Thus, advantageously, the use of CNTs in designing the PCB provides for a condensed layout of electrical and electronic components on the PCB. The illustrative PCB shown in FIG. 5 is a 6-layer PCB: the first (or top) layer (represented by reference numeral 6a) includes the CNT traces; the second layer (represented by reference numeral 6b) includes the power interface; the third layer (optional) (represented by reference numeral 6c) includes the heat sink; the fourth layer (represented by reference numeral 6d) includes the control interface; the fifth layer (represented by reference numeral 6e) includes the Radio Frequency (RF) shielding; and the sixth layer (represented by 6f) includes the Electro-Magnetic shielding. It will be understood that the simplified representation in FIG. 5 is merely for illustration and example. In alternate embodiments, devices may be composed of 1-24 (or, higher) PCB layers.

### CNTs for PCB Traces by Physical Vapor Deposition (PVD)

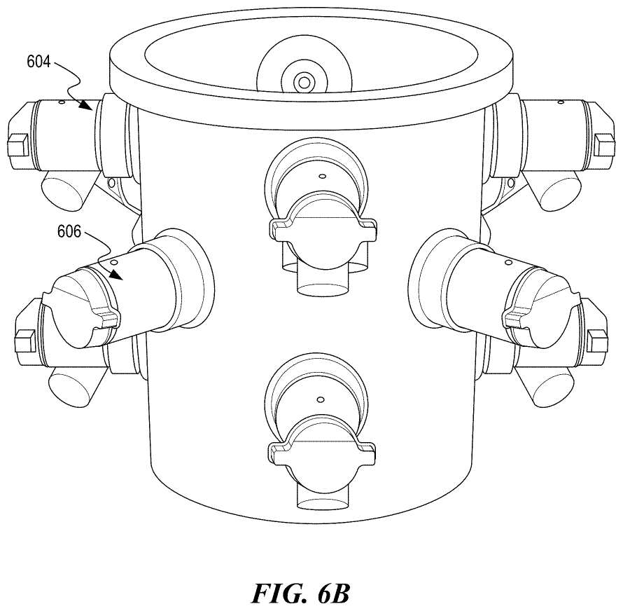

FIG. 6A illustrates a simplified diagram of the process of physical vapor deposition to impregnate PCBs with CNT traces using physical vapor deposition (PVD). The PVD technique disclosed herein tenaciously affixes CNT traces onto a PCB patterned or an un-patterned substrate. The PVD technique disclosed herein is a multi-phased process beginning with the formation of CNTs on a platen (e.g., represented by reference numeral 15) that results in billions of vertically-positioned CNTs (represented by reference numeral 8; also called a CNT forest) supported on the platen. The platen (e.g., a polished silicon or metallic plate) supporting the CNT forest is placed inside a chamber that handles vacuum conditions (e.g., between 1×10⁻¹² to 1×10⁻¹⁴ atmospheres). A PCB blank (reference numeral 11), which is the target, is positioned inside the chamber at about 0.25 m-1 m from the platen.

A laser technique (e.g., Laser-Induced Forward Transfer or LIFT) may be used to transfer the vertically-positioned CNTs from the platen to a PCB blank. A laser knife (represented by reference numeral 67) is focused at the rear end of the platen. As a result of excitation by the laser, the CNTs separate from the platen. Specifically, the platen material is superheated and launches CNTs positioned at the front edge of the platen. Consequently, CNTs travel at ballistic speeds in a vapor cloud through space (represented by reference numeral 10) within the chamber. The trajectory of CNTs as they travel in the cloud is represented by reference numeral 9. CNTs landing on the PCB blank (reference numeral 11) are aligned (represented by reference numeral 12) to the trace line patterns. The alignment of impregnated CNTs on the PCB blank is in parallel with one another, in a butt-jointed arrangement from end-to-end of the PCB blank. At least one advantage of the disclosed system is that misorientation and/or misalignment of the impregnated CNTs on the PCB is eliminated.

It will be understood that the disclosed system (including the vacuum conditions in the chamber) enables Van der Waals forces to cause the perfect or near-perfect alignment of CNTs on the PCB. Van der Waals forces generally include most types of forces such as attraction and repulsions between atoms, molecules, and surfaces, and/or other intermolecular forces. In some optional embodiments, the PCB target is mounted to a gimble (represented as reference numeral 13) for stability and a backsplash (represented by reference numeral 14) is used to collect unused CNTs. It will be understood that the discussions in FIG. 6A are for illustration and example. In alternate embodiments, suitable modifications can be made to the setup as will occur to one of ordinary skill.

FIG. 6B illustrates a vacuum chamber as part of a system for impregnating PCBs with CNTs. The PVD technique disclosed herein occurs within a chamber configured to handle vacuum conditions. The chamber is fitted with multiple ports (such as ports 604, 606) connected to vacuum pumps that maintain vacuum conditions (e.g., between 1×10⁻¹² to 1×10⁻¹⁴ atmospheres). Once the vacuum conditions are established within the chamber, the vacuum conditions are maintained within the chamber for a specified time duration (at least until the process occurring within the chamber is completed). The chamber can also be fitted with maintenance ports, e.g., for cleaning and routine maintenance. In some embodiments, the chamber can be 1-3 m in circumference and 2-15 m tall. The disclosed chamber serves multiple purposes: to provide enough area for heat dissipation at the site where PCB targets are placed, to prevent deformation and damage to the PCB targets, and to provide enough capacity to produce multiple patterned PCBs in each impregnation session that the PVD technique is applied. Further, using the disclosed chamber provides benefits of fixed impregnation, proper orientation (due to van der Waal forces), and densification of CNTs on the PCB substrate. Consequently, PCBs generated using the methods and systems disclosed herein allow for PCBs that function properly and reliably for long periods of time. In contrast to conventional PVD techniques, disclosed embodiments utilize the chamber equipped to maintain vacuum (or, near vacuum conditions) for a specified time duration which achieves ballistic ejection speeds of the CNTs from the platen, resulting in a perfect or near-perfect alignment of CNT traces on the PCB.

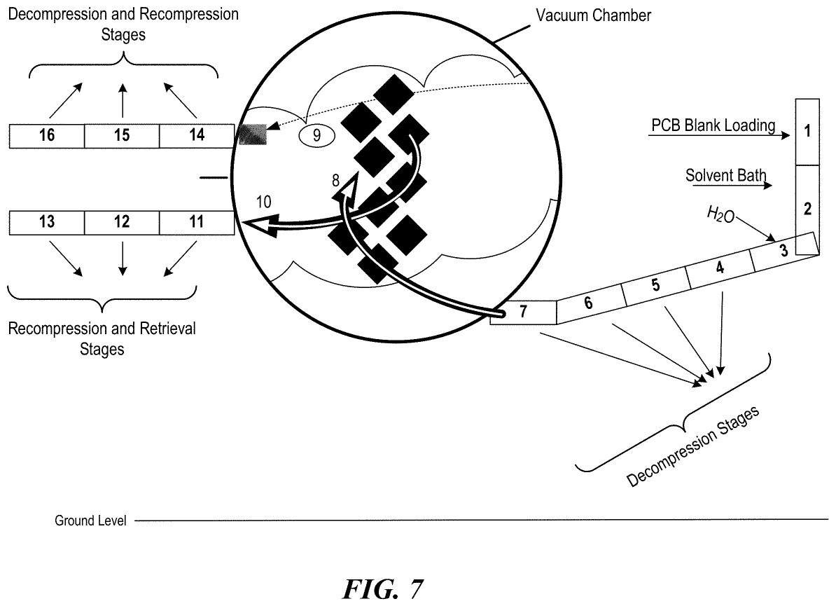

FIG. 7 illustrates a simplified diagram showing a system for generating PCBs impregnated with CNTs. The technology disclosed herein is not limited to a specific physical vapor deposition technique and is compatible with suitable PVD methodologies and processes. In some embodiments, the generation of PCBs impregnated with CNTs may be accomplished in multiple stages. For example, FIG. 7 illustrates a thirteen (13) stage system to ensure the proper maintenance of vacuum conditions allowing for near continuous generation of PCBs impregnated with CNTs. Also, FIG. 7 shows that the system includes a vacuum chamber equipped to maintain perfect vacuum or near perfect vacuum conditions. The vacuum chamber is used in one of the 13 stages.

Individual stages (shown with numbered rectangles in FIG. 7) of the system occur inside respective chambers. Chambers are connected to one another by bulkheads. Within each chamber, non-interlocking conveyor belts are contained entirely within a respective stage. At the boundary of a stage, interlocking doors lead to the subsequent stage. The doors do not open until pressure gradients are satisfied and/or processes in a respective stage are complete. The chambers used in each stage are made of high-strength stainless steel having a wall-thickness of around 9 inches.

At stage 1 of the system, PCB blanks are loaded at ambient pressure into the system through a port. Loading the PCB blanks causes the PCB blanks to be placed onto the first of six conveyor belts of the system. In some embodiments, thirty PCB blanks can be introduced into the system with a single load. The PCB blanks travel from one stage to another, starting from stage 1. In stage 2, the PCB blanks are subjected to a solvent bath to remove any particulate or chemical sub-stances that might contaminate a subsequent PVD process occurring inside the vacuum chamber. In stage 3, the PCB blanks are subjected to a water bath and dryer to remove any latent materials, including residual solvents from stage 2. Stages 4, 5, and 6 are decompression stages occurring inside respective chambers. For example, stages 4, 5, and 6 respectively occur inside an initial decompression chamber achieving a vacuum condition of −50 kPa, a secondary decompression chamber achieving a vacuum condition of −150 kPa, and a tertiary decompression chamber achieving a vacuum condition of −300 kPa. Stage 7, occurring right before the blanks are loaded inside the vacuum chamber, can be regarded as the equalization pressure stage in which blanks are subjected to −300 kPa until pressure measurements inside the vacuum chamber and pressure measurements in stage 7 are the same. It will be understood that deviations between pressure measurements inside the vacuum chamber and pressure measurements in stage 7 can result in distortion of the PCB blanks and/or damage to the equipment. Stages 4-7 are each connected to vacuum pumps for evacuating the associated chambers and also for evacuating the vacuum chamber.

Stage 8 depicts the shuttle of PCB blanks to positions within the vacuum chamber (alternatively termed as the “process vessel”). In some embodiments, the vacuum chamber has an internal diameter of 2.51 meters, an external diameter of 2.74 meters, and a height of 9.14 meters feet from the ground level. Stage 9 depicts the physical vapor deposition process inside the vacuum chamber. Stage 10 depicts the shuttle of impregnated PCB blanks to a retrieval chute. Stages 11-13 depict the three recompression stages that allow stage-wise increases in pressure resulting in return of the vacuum conditions to ambient pressure. For example, in stage 11, the pressure is increased from −300 kPa to −200 kPa. In stage 12, the pressure is increased from −200 kPa to −100 kPa. In stage 13, the pressure is increased from −100 kPa to ambient pressure. Eventually, PCBs impregnated with CNT traces are retrieved at the output of stage 13.

Furthermore, stages 14-16 are used for loading CNTs into the system. For example, in stages 14-16, a platen supporting vertically-positioned CNTs is loaded into the vacuum chamber. Before use inside the vacuum chamber, the CNTs supported on the platen are subjected to stage-wise decreases in pressure starting (in stage 16) from ambient pressure and terminating (in stage 14) to the vacuum conditions associated with the chamber. Eventually, the platen supporting the CNTs are positioned within the vacuum chamber for use in another session of generating PCBs impregnated with CNTs.

It will be understood that the above system is fully automated. Stages of the above system are implemented using sensors and sensitive electronic equipment that can be remotely controlled via a computing device (such as a computer server).

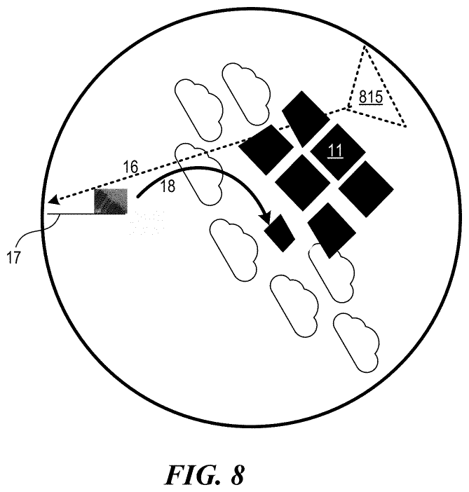

FIG. 8 illustrates a conceptual diagram showing CNT vapors generated as a result of physical vapor deposition. For example, FIG. 8 shows PCB blanks 11 (i.e., unimpregnated blanks) positioned on one side (e.g., the right side) of a chamber that is equipped to handle vacuum conditions. Each blank has a pattern (e.g., a positive pattern or a negative pattern) placed on it. After the blanks are appropriately positioned, a platen 17 supporting a large number (approximately 3 billion) of CNTs are positioned on the other side (e.g., the left side) of the chamber. A laser beam 16 (e.g., represented with the dotted line) is generated from a laser 815 and focused on the back of the platen supporting the CNTs. Excitation by the laser beam 16 causes the CNTs to be expelled from the front of the platen row-by-row and turn into super-heated vapor (e.g., represented as clouds in FIG. 8). Each vapor constitutes millions of CNTs. The super-heated vapors comprising CNTs travel (shown with reference numeral 18) at ballistic speeds and get deposited on the PCB blanks 11. The chamber is maintained at vacuum conditions (approximately between 1×10⁻¹² to 1×10⁻¹⁴ atmospheres) during the PVD process. The speeds of the CNTs traveling from the platen and the vacuum conditions inside the chamber results in the implantation/impregnation of the PCB blanks 11. Van der Vaal forces (including attraction and repulsions between CNTs) ensure the alignment of CNT traces parallel to one another in butt-jointed fashion, based on the pattern (e.g., a positive pattern or a negative pattern) on each blank.

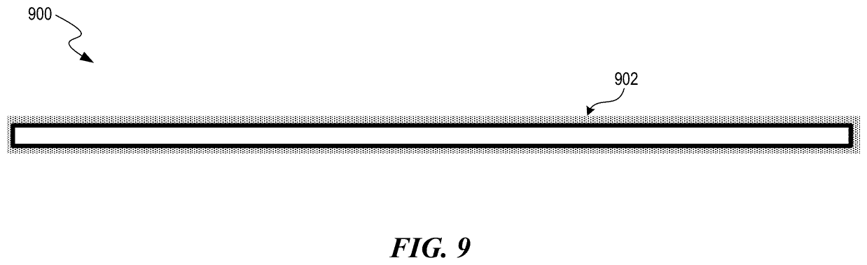

FIG. 9 illustrates an example of an impregnated PCB 900. For example, FIG. 9 shows a pattern 902 etched (e.g., using lithography) on the surface of an impregnated PCB. Upon retrieval of the impregnated blanks, the pattern is removed, and the surface of each PCB blank is passivated with a sealant. For example, the impregnated PCB is spray-coated with a protective coating and inserted in a hermetically sealed container. In some embodiments, additional steps can be undertaken at the ends of the impregnated PCB to supply electrical power to the impregnated PCB. The cross section of the impregnated PCB can have a thickness ranging from 2-3 millimeters to a few centimeters. The disclosed method of creating CNT traces on PCB blanks is a single step application that eliminates the need for minimizing tolerance errors on each layer of the PCB blank and in-between layers of the PCB blank.

Using the disclosed methods and system, line patterns at the sub-10 μm level can be achieved over areas spanning cm². In this manner, multilayer transfers can successfully be used to manufacture traces on patterned PCB, eliminating the need for metals, and creating a near optical trace pattern that requires no additional processing. The disclosed process is well-suited for industrial scale applications (e.g. several hundred micrometers to several hundred nanometers).

Some embodiments of the disclosed technology are now presented in clause-based format.

1. A method for impregnating printed circuit boards (PCBs) with carbon nanotubes (CNTs) comprising:

positioning a plurality of PCB blanks at a site inside a chamber equipped for maintaining vacuum conditions over a specified time duration;

positioning a platen supporting a plurality of CNTs inside the chamber;

exciting the plurality of CNTs with a laser beam causing ejection of the CNTs from the platen for implantation on the PCB blanks; and

collecting the plurality of PCB blanks impregnated with traces of the plurality of CNTs, wherein the traces of the plurality of CNTs are arranged in parallel with one another according to a butt-jointed arrangement from end-to-end on the plurality of PCB blanks.

2. The method of clause 1, wherein the chamber equipped for maintaining vacuum conditions includes a plurality of ports connected to vacuum pumps that are configured to maintain the vacuum conditions ranging between 1×10⁻¹² atmospheres to 1×10⁻¹⁴ atmospheres, and wherein the chamber equipped for maintaining vacuum conditions is made of stainless-steel material.

3. The method of clause 1, wherein the plurality of PCB blanks impregnated with the traces of the plurality of CNTs are created, at least in part, as a result of maintaining the vacuum conditions over the specified time duration and the exciting the plurality of CNTs with the laser beam.

4. The method of clause 1, wherein the plurality of PCB blanks impregnated with the traces of the plurality of CNTs are used in design of non-volatile memory for use in an electronic device.

5. The method of clause 1, wherein the plurality of PCB blanks impregnated with the traces of the plurality of CNTs correspond to deposition of the traces of the plurality of CNTs into patterned pathways on the plurality of PCB blanks.

6. The method of clause 1, wherein the chamber equipped for maintaining vacuum conditions allows heat dissipation at the site within the chamber where the plurality of PCB blanks are positioned and prevents deformation and damage to the plurality of PCB blanks.

7. The method of clause 1, wherein the plurality of PCB blanks impregnated with the traces of the plurality of CNTs provide security against radio frequency (RF) interference attacks based on elimination of ischemic emissions, and wherein the plurality of PCB blanks impregnated with the traces of the plurality of CNTs are applied for use in secure, computational, storage, sensor, autonomous, or communications devices.

8. The method of clause 1, wherein the laser beam is applied at a rear end of the platen for row-wise expulsion of CNTs located in a front end of the platen.

9. The method of clause 8, wherein the site where the plurality of PCB blanks is positioned is a first site, and wherein the platen is positioned at a second site such that the first site and the second site face one another inside the chamber.

10. The method of clause 1, further comprising:

removing patterns etched on a surface of the plurality of PCB blanks impregnated with the traces of the plurality of CNTs; and

passivating, with a sealant, the surface of the plurality of PCB blanks impregnated with the traces of the plurality of CNTs.

11. The method of clause 1, further comprising:

subjecting the plurality of PCB blanks impregnated with the traces of the plurality of CNTs to stage-wise increases in pressure resulting in return of the vacuum conditions to ambient pressure.

12. The method of clause 11, wherein the stage-wise increases in pressure is applied inside one or more recompression chambers that are located external to the chamber equipped for maintaining the vacuum conditions.

13. The method of clause 1, wherein, prior to positioning the platen supporting the plurality of CNTs inside the chamber, the platen is subjected to stage-wise decreases in pressure starting from ambient pressure and terminating in the vacuum conditions associated with the chamber.

14. The method of clause 13, wherein the stage-wise decreases in pressure is applied inside one or more decompression chambers that are located external to the chamber equipped for maintaining the vacuum conditions.

15. The method of clause 1, wherein the specified time duration starts from a time instant of positioning the plurality of PCB blanks and ends with a time instant of collecting the plurality of PCB blanks impregnated with the traces of the plurality of CNTs.

16. The method of clause 1, wherein the butt-jointed arrangement eliminates misorientation or misalignment of the traces of the plurality of CNTs.

17. The method of clause 1, wherein the PCB blanks impregnated with the traces of the plurality of CNTs provide one or more of:

(i) near-optical speed of electron transport between components on a PCB blank,

(ii) rad-hard design based on the plurality of CNTs having immunity to ionizing radiation,

(iii) security against attacks and interrogations by sources of excitation,

(iv) savings in energy consumption based on low resistivity of the traces of the plurality of CNTs,

(vi) low-weight and flexible substrates for use in microelectronic devices, and

(v) compact design based on eliminating resistors, capacitors, solid-state disks, and hard drives.

18. The method of clause 17, wherein the PCB blanks impregnated with the traces of the plurality of CNTs is generated by a single step application that eliminates steps related to layering and minimizing tolerance errors of a PCB blank and in-between layers of the PCB blank.

19. The method of clause 1, wherein the PCB blanks impregnated with the traces of the plurality of CNTs excludes a use of metals and further wherein the plurality of CNTs includes semiconducting single-wall CNTs (sSWNTs).

20. The method of clause 1, wherein, under the vacuum conditions generated within the chamber, alignment and densification of the traces of the plurality of CNTs is achieved, resulting in resilience of the traces of the plurality of CNTs to bending and breaking.

Some of the embodiments described herein are described in the general context of methods or processes, which may be implemented in one embodiment by a computer program product, embodied in a computer-readable medium, including computer-executable instructions, such as program code, and executed by computers in networked environments. A computer-readable medium may include removable and non-removable storage devices including, but not limited to, Read-Only Memory (ROM), Random Access Memory (RAM), compact discs (CDs), digital versatile discs (DVD), etc. Therefore, the computer-readable media may include a non-transitory storage media. Generally, program modules may include routines, programs, objects, components, data structures, etc. that perform particular tasks or implement particular abstract data types. Computer- or processor-executable instructions, associated data structures, and program modules represent examples of program code for executing steps of the methods disclosed herein. The particular sequence of such executable instructions or associated data structures represents examples of corresponding acts for implementing the functions described in such steps or processes.

Some of the disclosed embodiments may be implemented as devices or modules using hardware circuits, software, or combinations thereof. For example, a hardware circuit implementation may include discrete analog and/or digital components that are, for example, integrated as part of a printed circuit board. Alternatively, or additionally, the disclosed components or modules may include any number of process, memory and interconnect components (e.g. Application Specific Integrated Circuit (ASIC) and/or Field Programmable Gate Array (FPGA), optical or electrical interconnects, volatile or nonvolatile memory devices, etc.). Some implementations may additionally or alternatively include a digital signal processor (DSP) that is a specialized microprocessor with an architecture optimized for the operational needs of digital signal processing associated with the disclosed functionalities of this application. Similarly, the various components or sub-components within each module may be implemented in software, hardware or firmware. The connectivity between the modules and/or components within the modules may be provided using any one of the connectivity methods and media that is known in the art, including, but not limited to, communications over the Internet, wired, or wireless networks using the appropriate protocols.

The foregoing description of embodiments has been presented for purposes of illustration and description. The foregoing description is not intended to be exhaustive or to limit embodiments of the present invention(s) to the precise form disclosed, and modifications and variations are possible in light of the above teachings or may be acquired from practice of various embodiments. The embodiments discussed herein were chosen and described in order to explain the principles and the nature of various embodiments and their practical application to enable one skilled in the art to utilize the present invention(s) in various embodiments and with various modifications as are suited to the particular use contemplated. The features of the embodiments described herein may be combined in all possible combinations of methods, apparatus, modules, systems, and computer program products.

I/we claim:

1. A method for impregnating printed circuit boards (PCBs) with carbon nanotubes (CNTs) comprising:
positioning a plurality of PCB blanks at a site inside a chamber equipped for maintaining vacuum conditions over a specified time duration;
positioning a platen supporting a plurality of CNTs inside the chamber;
exciting the plurality of CNTs with a laser beam causing ejection of the CNTs from the platen for implantation on the PCB blanks; and
collecting the plurality of PCB blanks impregnated with traces of the plurality of CNTs, wherein the traces of the plurality of CNTs are arranged in parallel with one another according to a butt-jointed arrangement from end-to-end on the plurality of PCB blanks.

2. The method of claim 1, wherein the chamber equipped for maintaining vacuum conditions includes a plurality of ports connected to vacuum pumps that are configured to maintain the vacuum conditions ranging between 1×10⁻¹² atmospheres to 1×10⁻¹⁴ atmospheres, and wherein the chamber equipped for maintaining vacuum conditions is made of stainless-steel material.

3. The method of claim 1, wherein the plurality of PCB blanks impregnated with the traces of the plurality of CNTs are created, at least in part, as a result of maintaining the vacuum conditions over the specified time duration and the exciting the plurality of CNTs with the laser beam.

4. The method of claim 1, wherein the plurality of PCB blanks impregnated with the traces of the plurality of CNTs are used in design of non-volatile memory for use in an electronic device.

5. The method of claim 1, wherein the plurality of PCB blanks impregnated with the traces of the plurality of CNTs correspond to deposition of the traces of the plurality of CNTs into patterned pathways on the plurality of PCB blanks.

6. The method of claim 1, wherein the chamber equipped for maintaining vacuum conditions allows heat dissipation at the site within the chamber where the plurality of PCB blanks are positioned and prevents deformation and damage to the plurality of PCB blanks.

7. The method of claim 1, wherein the plurality of PCB blanks impregnated with the traces of the plurality of CNTs provide security against radio frequency (RF) interference attacks based on elimination of ischemic emissions, and wherein the plurality of PCB blanks impregnated with the traces of the plurality of CNTs are applied for use in secure computational, storage, sensor, autonomous, or communications devices.

8. The method of claim 1, wherein the laser beam is applied at a rear end of the platen for row-wise expulsion of CNTs located in a front end of the platen.

9. The method of claim 8, wherein the site where the plurality of PCB blanks is positioned is a first site, and wherein the platen is positioned at a second site such that the first site and the second site face one another inside the chamber.

10. The method of claim 1, further comprising:
removing patterns etched on a surface of the plurality of PCB blanks impregnated with the traces of the plurality of CNTs; and
passivating, with a sealant, the surface of the plurality of PCB blanks impregnated with the traces of the plurality of CNTs.

11. The method of claim 1, further comprising:
subjecting the plurality of PCB blanks impregnated with the traces of the plurality of CNTs to stage-wise increases in pressure resulting in return of the vacuum conditions to ambient pressure.

12. The method of claim 11, wherein the stage-wise increases in pressure is applied inside one or more recompression chambers that are located external to the chamber equipped for maintaining the vacuum conditions.

13. The method of claim 1, wherein, prior to positioning the platen supporting the plurality of CNTs inside the chamber, the platen is subjected to stage-wise decreases in pressure starting from ambient pressure and terminating in the vacuum conditions associated with the chamber.

14. The method of claim 13, wherein the stage-wise decreases in pressure is applied inside one or more decompression chambers that are located external to the chamber equipped for maintaining the vacuum conditions.

15. The method of claim 1, wherein the specified time duration starts from a time instant of positioning the plurality of PCB blanks and ends with a time instant of collecting the plurality of PCB blanks impregnated with the traces of the plurality of CNTs.

16. The method of claim 1, wherein the butt-jointed arrangement eliminates misorientation or misalignment of the traces of the plurality of CNTs.

17. The method of claim 1, wherein the PCB blanks impregnated with the traces of the plurality of CNTs provide one or more of:
(i) near-optical speed of electron transport between components on a PCB blank,
(ii) rad-hard design based on the plurality of CNTs having immunity to ionizing radiation,
(iii) security against attacks and interrogations by sources of excitation,
(iv) savings in energy consumption based on low resistivity of the traces of the plurality of CNTs,
(vi) low-weight and flexible substrates for use in microelectronic devices, and
(v) compact design based on eliminating resistors, capacitors, solid-state disks, and hard drives.

18. The method of claim 17, wherein the PCB blanks impregnated with the traces of the plurality of CNTs is generated by a single step application that eliminates steps related to layering and minimizing tolerance errors of a PCB blank and in-between layers of the PCB blank.

19. The method of claim 1, wherein the PCB blanks impregnated with the traces of the plurality of CNTs excludes a use of metals and further wherein the plurality of CNTs includes semiconducting single-wall CNTs (sSWNTs).

20. The method of claim 1, wherein, under the vacuum conditions generated within the chamber, alignment and densification of the traces of the plurality of CNTs is achieved, resulting in resilience of the traces of the plurality of CNTs to bending and breaking.
